(19) United States
(12) Patent Application Publication
(10) Pub. No.: US 2019/0241766 A1
(43) Pub. Date: Aug. 8, 2019

(54) POLISHING LIQUID COMPOSITION

(71) Applicant: KAO CORPORATION, Tokyo (JP)

(72) Inventor: Haruhiko DOI, Wakayama (JP)

(73) Assignee: KAO CORPORATION, Tokyo (JP)

(21) Appl. No.: 16/338,184

(22) PCT Filed: Sep. 28, 2017
(86) PCT No.: PCT/JP2017/035262

§ 371 Date: Mar. 29, 2019

(30) Foreign Application Priority Data
Sep. 29, 2016 (JP) 2016-192157
Aug. 24, 2017 (JP) 2017-161425

(51) Int. Cl. C09G 1/02; H01L 21/306

(52) U.S. Cl. CPC C09G 1/02; H01L 21/30625

(57) ABSTRACT

Provided is a polishing composition capable of improving polishing selectivity and reducing polishing unevenness while increasing polishing rate.

The present disclosure relates to a polishing composition containing; cerium oxide particles A; a polysaccharide B having a weight average molecular weight of 800 or more and 2800 or less; and water.

### TECHNICAL FIELD

The present disclosure relates to a polishing composition containing cerium oxide particles, and a method for producing a semiconductor substrate using the same, and a method for polishing a substrate using the same.

### BACKGROUND ART

Chemical mechanical polishing (CMP) is a surface planarization technique that includes bringing a processing surface of a substrate to be polished into contact with a polishing pad, supplying a polishing liquid to a contact part between the substrate and the polishing pad, and moving them relatively. Thereby, unevenness portions on the surface of the substrate can be reacted chemically and removed mechanically.

The CMP technique is presently essential for planarization of interlayer insulating films, formation of a shallow trench isolation structure (hereinafter, also referred to as an “element isolation structure”), formation of plugs and buried metal wiring, etc., in the production process of semiconductor elements. In recent years, multilayering and higher definition of semiconductor elements have progressed rapidly, and further improvements in yield and throughput of the semiconductor elements have been demanded. Accordingly, in the CMP processes, a higher polishing rate with no polishing flaws has been demanded. For example, in the formation process of the shallow trench isolation structure, it is desired to improve polishing selectivity of a polishing stopper film (e.g., silicon nitride film) with respect to a film to be polished (e.g., silicon oxide film) (in other words, selectivity in polishing that allows the polishing stopper film to be less likely to be polished than the film to be polished), along with an improvement in the polishing rate.

Patent Document 1 discloses, as a polishing agent for forming an element isolation structure, a CMP polishing agent that contains: cerium oxide particles; a dispersant; an additive selected from water-soluble organic low-molecules having an anionic group such as a —COOM group, a phenolic OH group, a —SO₃M group, an —OSO₃H group, a —PO₄M₂ group, or a —PO₃M₂ group (wherein M is H, NH₄, or a metal atom such as Na or K); and water.

Patent Document 2 discloses a polishing agent that contains: (A) oxide fine particles; (B) at least one selected from the group consisting of a monosaccharide, an oligosaccharide made up of 2 to 20 monosaccharides linked together, sugar alcohols of these, and sugar esters of these; (C) a benzotriazole-based compound; and (D) water.

Patent Document 3 discloses a polishing agent that contains: water; cerium oxide particles; saccharides with 140 or less carbon atoms; a nonionic surfactant; and an organic acid.

Patent Document 4 discloses a polishing agent that contains: a water-soluble inclusion compound such as a cyclic oligosaccharide; polishing abrasive grains; and water.

Patent Document 5 discloses a polishing agent that contains: cerium oxide abrasive grains; water; a polysaccharide; and at least one selected from the group consisting of a water-soluble organic polymer and an anionic surfactant.

Patent Document 6 discloses a polishing agent that contains: water;

abrasive grains containing a hydroxide of a tetravalent metal element; an α-glucose polymer; and a cationic polymer.

### PRIOR ART DOCUMENTS

### Patent Documents

Patent Document 1: JP 2001-007060 A
Patent Document 2: JP 2004-055861 A
Patent Document 3: JP 2015-129217 A
Patent Document 4: JP 2011-103410 A
Patent Document 5: WO 2010/104085
Patent Document 6: WO 2015/052988

### DISCLOSURE OF INVENTION

### Problem to be Solved by the Invention

Recently, since high integration has progressed in the semiconductor field, wiring becomes complicated and microfabrication is required. Because of this, in the CMP polishing, it is demanded to further improve the polishing selectivity while increasing the polishing rate. Further, although various additives have been studied to improve the polishing selectivity and increase the polishing rate, such additives in polishing compositions sometimes cause polishing unevenness.

The present disclosure provides a polishing composition capable of improving the polishing selectivity and reducing the polishing unevenness while increasing the polishing rate, a method for producing a semiconductor substrate using the same, and a method for polishing a substrate using the same.

### Means for Solving Problem

The present disclosure relates to a polishing composition (hereinafter, also referred to as “polishing composition of the present disclosure”), containing: cerium oxide particles A; a polysaccharide B having a weight average molecular weight of 800 or more and 2800 or less; and water.

The present disclosure relates to a method for producing a semiconductor substrate, including polishing a substrate to be polished using the polishing composition of the present disclosure.

The present disclosure relates to a method for polishing a substrate, including polishing a substrate to be polished using the polishing composition of the present disclosure, wherein the substrate to be polished is a substrate for producing a semiconductor substrate.

### Effects of the Invention

The present disclosure can produce an effect of providing a polishing composition capable of improving the polishing selectivity and reducing the polishing unevenness while increasing the polishing rate.

### DESCRIPTION OF THE INVENTION

The present inventors found as a result of keen studies that, by adding a predetermined polysaccharide B to a polishing composition containing cerium oxide (hereinafter, also referred to as “ceria”) particles as abrasive grains, it is possible to improve the polishing selectivity and reduce the polishing unevenness while increasing the polishing rate. Thus, the present invention has been accomplished.

Specifically, the present disclosure relates to a polishing composition, containing: cerium oxide particles A; a polysaccharide B having a weight average molecular weight of 800 or more and 2800 or less; and water. The polishing composition of the present disclosure can improve the polishing selectivity and reduce the polishing unevenness while increasing the polishing rate.

Although the precise mechanism that can produce the effect of the present disclosure is not clarified, the following are assumed.

In the polishing using polishing compositions containing cerium oxide particles as abrasive grains, generally a polishing stopper film such as a silicon nitride film is oxidized by hydrolysis by water molecules, and the composition of the polishing stopper film becomes almost equal to the composition of a film to be polished such as a silicon oxide film. Because of this, the polishing stopper film is easily polished by cerium oxide particles. On the other hand, in the polishing using the polishing composition of the present disclosure, the polysaccharide B having a predetermined weight average molecular weight hydrates with water molecules, and suppresses the hydrolysis of the polishing stopper film such as a silicon nitride film, thereby suppressing the polishing by cerium oxide particles. Moreover, the polishing composition of the present disclosure containing the polysaccharide B can have a high ability to suppress the polishing of the polishing stopper film such as a silicon nitride film, thereby suppressing the polishing unevenness of the polishing stopper film such as a silicon nitride film.

Note that the present disclosure is not limited to these mechanisms.

The term “polishing selectivity” in the present disclosure is synonymous with a ratio of the polishing rate (polishing rate ratio) for the film to be polished with respect to the polishing rate for the polishing stopper film (the polishing rate for the film to be polished/the polishing rate for the polishing stopper film). High “polishing selectivity” means a high polishing rate ratio.

[Cerium Oxide (Ceria) Particles A]

The polishing composition of the present disclosure contains cerium oxide particles A (hereinafter, also referred to as “particles A” simply) as polishing abrasive grains. The production method, shape and surface condition of the particles A are not particularly limited. Examples of the particles A include colloidal ceria, amorphous ceria, and ceria-coated silica. The colloidal ceria can be obtained through a buildup process by the method described in Examples 1-4 of JP 2010-505735 A, for example. The amorphous ceria can be obtained by baking and pulverizing a cerium compound such as cerium carbonate or cerium nitrate, for example. The ceria-coated silica may be composite particles in which at least part of the surfaces of silica particles are coated with particulate ceria by the method described in Examples 1-14 of JP 2015-063451 A or the method described in Examples 1-4 of JP 2013-119131 A, for example. The composite particles can be obtained by depositing ceria on silica particles, for example. The colloidal ceria is preferred from the viewpoint of improving the polishing rate. The ceria-coated silica is preferred from the viewpoint of reducing residues after polishing. The particles A may be one kind of ceria particles, or a combination of two or more kinds of ceria particles.

The average primary particle diameter of the particles A is preferably 5 nm or more, more preferably 10 nm or more, and further preferably 20 nm or more from the viewpoint of improving the polishing rate, while the average primary particle diameter thereof is preferably 300 nm or less, more preferably 200 nm or less, and further preferably 150 nm or less from the viewpoint of reducing polishing flaws. In the present disclosure, the average primary particle diameter of the particles A is calculated using a BET specific surface area S (m²/g) calculated by a BET (nitrogen adsorption) method. The BET specific surface area can be measured by a method described in the examples.

The particles A may have, e.g., a substantially spherical shape, a polyhedral shape, or a raspberry shape.

When the total content of the particles A, the polysaccharide B and water is assumed to be 100 mass %, the content of the particles A in the polishing composition of the present disclosure is preferably 0.05 mass % or more, more preferably 0.10 mass % or more, and further preferably 0.20 mass % or more from the viewpoint of increasing the polishing rate and improving the polishing selectivity, while the content thereof is preferably 10.0 mass % or less, more preferably 7.5 mass % or less, further preferably 5.0 mass % or less, still further preferably 2.5 mass % or less, and even further preferably 1.0 mass % or less from the same viewpoint. When the particles A are a combination of two or more kinds of ceria particles, the content of the particles A is a total content thereof.

[Polysaccharide B]

The polishing composition of the present disclosure contains a polysaccharide B having a weight average molecular weight of 800 or more and 2800 or less (hereinafter, also referred to as “polysaccharide B” simply). The weight average molecular weight of the polysaccharide B is 800 or more, preferably 850 or more, more preferably 900 or more, further preferably 1000 or more, and still further preferably 1200 or more from the viewpoint of suppressing the polishing rate for the silicon nitride film, while the weight average molecular weight thereof is 2800 or less, preferably 2700 or less, more preferably 2600 or less, further preferably 2550 or less, still further preferably 2500 or less, and even further preferably 2300 or less from the viewpoint of improving the polishing rate ratio. The term “polysaccharide” in the present disclosure refers to a saccharide composed of two or more monosaccharides serving as constituent units. Here, the constituent unit of the polysaccharide refers to a monosaccharide constituting the polysaccharide. The polysaccharide B may be one kind of polysaccharide, or a combination of two or more kinds of polysaccharides.

In the present disclosure, the weight average molecular weight can be measured by gel permeation chromatography (GPC) under the following conditions using a liquid chromatograph (L-6000 high-speed liquid chromatograph manufactured by Hitachi, Ltd.).

Detector: Shodex RI, SE-61 differential refractometer detector

Column: “TSKgel (registered trademark) α-M” and “TSKgel (registered trademark) α-M” (manufactured by TOSHO CORPORATION) connected in series

Eluent: 50 mmol/LiBr aqueous solution

Column temperature: 40° C.

Flow rate: 1.0 mL/min

Reference polymer: monodispersed pullulan of known molecular weight (Shodex STD-P series)

The structure of the polysaccharide B may be a linear structure, a cyclic structure, or a branched structure. Among these, the branched structure is preferred from the viewpoint of increasing the polishing rate, improving the polishing selectivity and reducing the polishing unevenness.

In one embodiment, the polysaccharide B may be a water-soluble dietary fiber from the viewpoint of increasing the polishing rate, improving the polishing selectivity and reducing the polishing unevenness. Specifically, the polysaccharide B may be one kind or a combination of two or more kinds selected from indigestible glucan and polydextrose. The “indigestible glucan”, “polydextrose” and “water-soluble dietary fiber” in the present disclosure are indigestible polysaccharides that are not easily digested by human digestive enzymes.

A specific example of the indigestible glucan is “Fit Fiber (registered trademark)” manufactured by NIHON SHOKUHIN KAKO CO., LTD. Specific examples of the polydextrose include: “Litesse (registered trademark) III”, “Litesse (registered trademark) Powder”, Litesse (registered trademark) II”, “Litesse (registered trademark) Ultra (trademark)”, and “Litesse (registered trademark) Fiber HF” manufactured by Danisco; “STA-LITE (registered trademark) III”, “STA-LITE (registered trademark) Elite”, and “PROMITOR (trademark) 85” manufactured by Tate & Lyle; and “Sunfiber (registered trademark)” manufactured by Taiyo Kagaku Co., Ltd.

The indigestible glucan can be produced by heating a starch decomposition product in the presence of activated carbon, for example.

The polydextrose can be produced by heating glucose, sorbitol and citric acid in proportions of 89:10:1, for example.

In another embodiment, the polysaccharide B may be a saccharide in which monosaccharides serving as the constituent units are glucoses, or a condensate having a branched chain in which glucoses are linked by glucosidic linkage, these having a weight average molecular weight of 800 or more and 2800 or less, from the viewpoint of increasing the polishing rate, improving the polishing selectivity and reducing the polishing unevenness. These may be used alone or in a combination of two or more kinds. The number of the monosaccharides serving as the constituent units of the polysaccharide B is preferably 3 or more, more preferably 5 or more, and further preferably 10 or more from the viewpoint of reducing the polishing unevenness, while the number of the monosaccharides is preferably 20 or less from the same viewpoint. Moreover, the polysaccharide B is preferably a saccharide made up of 3 to 20 glucoses linked together, and more preferably a saccharide made up of 3 to 20 glucoses linked together where the constituent units are glucose only, from the viewpoint of increasing the polishing rate, improving the polishing selectivity and reducing the polishing unevenness.

The content of the polysaccharide B in the polishing composition of the present disclosure is preferably an amount effective in reducing the polishing unevenness from the viewpoint of reducing the polishing unevenness.

Specifically, when the total content of the particles A, the polysaccharide B and water is assumed to be 100 mass %, the content of the polysaccharide B is preferably 0.1 mass % or more, more preferably 0.2 mass % or more, further preferably 0.3 mass % or more, still further preferably 0.4 mass % or more, and even further preferably 0.5 mass % or more, while the content thereof is preferably 2.5 mass % or less, more preferably 2.0 mass % or less, further preferably 1.8 mass % or less, still further preferably 1.5 mass % or less, and even further preferably 1.1 mass % or less from the viewpoint of increasing the polishing rate and improving the polishing selectivity. The content of the polysaccharide B is preferably 0.1 mass % or more and 2.0 mass % or less, more preferably 0.2 mass % or more and 1.8 mass % or less, and further preferably 0.3 mass % or more and 1.5 mass % or less from the viewpoint of increasing the polishing rate, improving the polishing selectivity and reducing the polishing unevenness. When the polysaccharide B is a combination of two or more kinds of polysaccharides, the content of the polysaccharide B is a total content thereof.

A ratio B/A of the content of the polysaccharide B to the content of the particles A in the polishing composition of the present disclosure is preferably 0.01 or more, more preferably 0.1 or more, and further preferably 0.3 or more, while the ratio B/A is preferably 20 or less, more preferably 10 or less, and further preferably 5 or less from the viewpoint of increasing the polishing rate, improving the polishing selectivity and reducing the polishing unevenness.

[Compound C]

The polishing composition of the present disclosure preferably contains a compound C having an anionic group (hereinafter, also referred to as “compound C”) as a polishing aid from the viewpoint of increasing the polishing rate and improving the polishing selectivity. The compound C may be one kind or a combination of two or more kinds.

Examples of the anionic group of the compound C include a carboxylic acid group, a sulfonic acid group, a sulfate group, a phosphate group, and a phosphonic acid group. These anionic groups may take a form of neutralized salts. Examples of a counter ion, when the anionic group takes a form of a salt, include a metal ion, an ammonium ion, and an alkylammonium ion. Among these, the ammonium ion is preferred from the viewpoint of improving the quality of a semiconductor substrate.

The compound C may be at least one selected from a monovalent carboxylic acid, citric acid and an anionic polymer. Specific examples of the anionic polymer as the compound C include polyacrylic acid, polymethacrylic acid, polystyrene sulfonate, a copolymer of (meth)acrylic acid and monomethoxypolyethylene glycol mono(meth)acrylate, a copolymer of (meth)acrylate having an anionic group and monomethoxypolyethylene glycol mono(meth)acrylate, a copolymer of alkyl(meth)acrylate and (meth)acrylic acid and monomethoxypolyethylene glycol mono(meth)acrylate, alkali metal salts thereof, and ammonium salts thereof. Among these, the compound C is preferably at least one selected from polyacrylic acid and an ammonium salt thereof from the viewpoint of improving the quality of a semiconductor substrate.

When the compound C is an anionic polymer, the weight average molecular weight of the compound C is preferably 1,000 or more, more preferably 10,000 or more, and further preferably 20,000 or more, while the weight average molecular weight thereof is preferably 5,500,000 or less, more preferably 1,000,000 or less, and further preferably 100,000 or less from the viewpoint of increasing the polishing rate and improving the polishing selectivity. In the present disclosure, the weight average molecular weight of the compound C can be calculated in the same manner as the method for measuring the weight average molecular weight of the polysaccharide B.

When the compound C is a monovalent carboxylic acid, the compound C may be at least one selected from levulinic acid, propionic acid, vanillic acid, p-hydroxybenzoic acid, and formic acid. It is considered that the polishing composition of the present disclosure containing the monovalent carboxylic acid as the compound C can have favorable storage stability.

The content of the compound C in the polishing composition of the present disclosure is preferably 0.001 mass % or more, more preferably 0.0015 mass % or more, and further preferably 0.0025 mass % or more, while the content thereof is preferably 1.0 mass % or less, more preferably 0.8 mass % or less, and further preferably 0.6 mass % or less from the viewpoint of increasing the polishing rate and improving the polishing selectivity. When the compound C is a combination of two or more kinds, the content of the compound C is a total content thereof.

A ratio (C/A) of the content of the compound C to the content of the particles A in the polishing composition of the present disclosure is preferably 0.0001 or more, more preferably 0.0005 or more, and further preferably 0.001 or more, while the ratio (C/A) is preferably 1 or less, more preferably 0.1 or less, and further preferably 0.01 or less from the viewpoint of increasing the polishing rate and improving the polishing selectivity.

[Water]

The polishing composition of the present disclosure contains water as a medium. The water is preferably ion exchanged water, distilled water, or ultrapure water from the viewpoint of improving the quality of a semiconductor substrate. When the total content of the particles A, the polysaccharide B, water, and the compound C and undermentioned optional components to be added as needed is assumed to be 100 mass %, the content of water in the polishing composition of the present disclosure may be a remainder after subtracting the contents of the particles A, the polysaccharide B, the compound C, and the optional components.

[Optional Components]

The polishing composition of the present disclosure may contain optional components such as a pH regulator, a surfactant other than the compound C, a saccharide other than the polysaccharide B, a thickener, a dispersant, a rust-preventive agent, a basic substance, and a polishing rate improver within a range that does not impair the effect of the present disclosure. The content of the optional components is preferably 0.001 mass % or more, more preferably 0.0025 mass % or more, and further preferably 0.01 mass % or more from the viewpoint of improving the polishing rate, while the content thereof is preferably 1 mass % or less, more preferably 0.5 mass % or less, and further preferably 0.1 mass % or less from the viewpoint of improving the polishing selectivity.

The pH regulator may be, e.g., an acidic compound or an alkali compound. Examples of the acidic compound include: inorganic acids such as hydrochloric acid, nitric acid and sulfuric acid; and organic acids such as acetic acid, oxalic acid, citric acid and malic acid. Among these, the acidic compound is preferably at least one selected from hydrochloric acid, nitric acid and acetic acid, and more preferably at least one selected from hydrochloric acid and acetic acid from the viewpoint of versatility. Examples of the alkali compound include: inorganic alkali compounds such as ammonia and potassium hydroxide; and organic alkali compounds such as alkylamine and alkanolamine. Among these, the alkali compound is preferably at least one selected from ammonia and alkylamine, and more preferably ammonia from the viewpoint of improving the quality of a semiconductor substrate.

The surfactant other than the compound C may be, e.g., an anionic surfactant or a non-ionic surfactant other than the compound C. Examples of the anionic surfactant include alkyl ether acetate, alkyl ether phosphate, and alkyl ether sulfate. Examples of the non-ionic surfactant include non-ionic polymers such as polyacrylamide, and polyoxyalkylene alkyl ether, and polyoxyethylene distyrenated phenyl ether.

In one or more embodiments, the polishing composition of the present disclosure may not substantially contain a non-ionic surfactant. In the present disclosure, “not substantially contain a non-ionic surfactant” means that the content of the non-ionic surfactant in the polishing composition is 0.1 mass % or less. The content of the non-ionic surfactant in the polishing composition of the present disclosure is preferably less than 0.01 mass %, more preferably 0.005 mass % or less, and further preferably substantially 0 mass % from the viewpoint of increasing the polishing rate for a silicon oxide film and improving the polishing selectivity.

[Polishing Composition]

The polishing composition of the present disclosure can be produced by a production method including blending a slurry containing the particles A and water, the polysaccharide B, and as needed, the compound C and the optional components by a known method. For example, the polishing composition of the present disclosure may be a polishing composition produced by blending at least the particles A, the polysaccharide B and water. In the present disclosure, “blending” includes mixing the particles A, the polysaccharide B, water, and as needed, the compound C and the other optional components simultaneously or sequentially. The order of mixing is not particularly limited. The blending can be carried out using a mixer such as a homomixer, a homogenizer, an ultrasonic disperser, or a wet ball mill. The blending amount of each component in the production method of the polishing composition of the present disclosure can be the same as the above content of each component in the polishing composition of the present disclosure.

In one or more embodiments, the polishing composition of the present disclosure may be a one-pack type that is put on the market in a state in which all the components are mixed beforehand, or a two-pack type that is mixed in use. The two-pack type polishing composition is separated into a first liquid and a second liquid. For example, the polishing composition may be composed of a first liquid in which the particles A are mixed in water and a second liquid in which the polysaccharide B is mixed in water, and the first liquid and the second liquid are mixed in use. The first liquid and the second liquid may be mixed before being supplied to the surface of an object to be polished, or they may be separately supplied to the surface of a substrate to be polished and mixed thereon.

The pH of the polishing composition of the present disclosure is preferably 4.0 or more, more preferably 5.0 or more, and further preferably 6.0 or more, while the pH thereof is preferably 9.0 or less, more preferably 8.5 or less, and further preferably 8.0 or less from the viewpoint of increasing the polishing rate and improving the polishing selectivity. The pH of the polishing composition in the present disclosure is a value thereof at 25° C. measured using a pH meter. Specifically, the pH of the polishing composition in the present disclosure can be measured by a method described in the examples.

The “content of each component in the polishing composition” in the present disclosure refers to the content of the each component at the time the polishing composition is used for polishing. The polishing composition of the present disclosure may be preserved and provided in the form of a concentrate as long as its stability is not impaired. This is preferred because the production and transportation costs can be reduced. The concentrate of the polishing composition of the present disclosure can be diluted appropriately with the above aqueous medium as needed so as to be used in the polishing step. The dilution ratio is preferably 5 to 100 times.

[Film to be Polished]

A film to be polished by the polishing composition of the present disclosure may be, e.g., a silicon oxide film. The polishing composition of the present disclosure can be suitably used in polishing a silicon oxide film in the formation of the element isolation structure of a semiconductor substrate.

[Polishing Liquid Kit]

The present disclosure relates to a polishing liquid kit for producing the polishing composition, the kit composed of a dispersion liquid of the particles A, which is a dispersion liquid containing the particles A held in a container, and the polysaccharide B, which is held in a container different from the container of the dispersion liquid of the particles A. The polishing liquid kit of the present disclosure can provide a polishing composition capable of improving the polishing selectivity and reducing the polishing unevenness while increasing the polishing rate.

The polishing liquid kit of the present disclosure may be a polishing liquid kit (two-pack type polishing composition) in which a dispersion liquid containing the particles A (first liquid) and a solution containing the polysaccharide B (second liquid) are stored in a state of not being mixed with each other, and they are mixed in use. Water may be added as needed to the mixture of the first liquid and the second liquid for dilution. The second liquid may contain other components that can be blended in the polishing composition for use in polishing an object to be polished. Examples of the other components that can be blended in the polishing composition include the compound C, an acid, an oxidizer, a heterocyclic aromatic compound, an aliphatic amine compound, and an alicyclic amine compound. The first liquid and the second liquid each may contain optional components as needed. Examples of the optional components include a thickener, a dispersant, a rust-preventive agent, a basic substance, a polishing rate improver, a surfactant, and a macromolecular compound.

[Method for Producing Semiconductor Substrate]

The present disclosure relates to a method for producing a semiconductor substrate (hereinafter, also referred to as “production method of a semiconductor substrate of the present disclosure”), including polishing a film to be polished using the polishing composition of the present disclosure (hereinafter, also referred to as “polishing step using the polishing composition of the present disclosure”). The production method of a semiconductor substrate of the present disclosure can improve the polishing selectivity and reduce the polishing unevenness while increasing the polishing rate in the polishing step, thereby providing an effect of producing a semiconductor substrate with improved substrate quality efficiently.

As a specific example of the production method of a semiconductor substrate of the present disclosure, first, a silicon substrate is exposed to oxygen in an oxidation furnace so as to grow a silicon dioxide layer on its surface, and then a polishing stopper film such as a silicon nitride (Si₃N₄) film or a polysilicon film is formed on the silicon dioxide layer by, e.g., a CVD method (chemical vapor deposition method). Next, a trench is formed using a photolithography technique on the substrate including the silicon substrate and the polishing stopper film that is arranged on one principal surface of the silicon substrate (e.g., a substrate in which a polishing stopper film is formed on a silicon dioxide layer of a silicon substrate). Next, a silicon oxide (SiO₂) film for filling trench (film to be polished) is formed by, e.g., a CVD method using a silane gas and an oxygen gas. Thus, a substrate to be polished in which the polishing stopper film is covered with the film to be polished (silicon oxide film) is obtained. By forming the silicon oxide film, the trench is filled with silicon oxide of the silicon oxide film, and the surface of the polishing stopper film that is opposite to the surface facing the silicon substrate side is covered with the silicon oxide film. The surface of the silicon oxide film thus formed that is opposite to the surface facing the silicon substrate side has a difference in height formed correspondingly to the convexo-concave pattern of the lower layers. Next, the silicon oxide film is polished by the CMP method until at least the surface of the polishing stopper film that is opposite to the surface facing the silicon substrate side is exposed, more preferably until the surface of the silicon oxide film is flush with the surface of the polishing stopper film. The polishing composition of the present disclosure can be used in the polishing step by the CMP method.

In the polishing by the CMP method, uneven portions on the surface of the substrate to be polished are planarized by supplying the polishing composition of the present disclosure to a contact part between the substrate to be polished and a polishing pad in a state where the surface of the substrate to be polished and the polishing pad are in contact with each other, and moving them relatively. In the production method of a semiconductor substrate of the present disclosure, another insulating film may be formed between the silicon dioxide layer of the silicon substrate and the polishing stopper film, or another insulating film may be formed between the film to be polished (e.g., silicon oxide film) and the polishing stopper film (e.g., silicon nitride film).

In the polishing step using the polishing composition of the present disclosure, for example, the number of revolutions of the polishing pad can be set to 30 to 200 r/min, the number of revolutions of the substrate to be polished can be set to 30 to 200 r/min, the polishing load of a polishing device equipped with the polishing pad can be set to 20 to 500 g weight/cm², and the supply rate of the polishing composition can be set to 10 to 500 mL/min. When the polishing composition is a two-pack type polishing composition, the polishing rates for the film to be polished and the polishing stopper film as well as the polishing rate ratio (polishing selectivity) between the film to be polished and the polishing stopper film can be adjusted by adjusting the supply rates (or supply amounts) of the first liquid and the second liquid.

In the polishing step using the polishing composition of the present disclosure, the polishing rate for the film to be polished (e.g., silicon oxide film) is preferably 2000 Å/min or more, more preferably 3000 Å/min or more, and further preferably 4000 Å/min or more from the viewpoint of improving the productivity.

In the polishing step using the polishing composition of the present disclosure, the polishing rate for the polishing stopper film (e.g., silicon nitride film) is preferably 500 Å/min or less, more preferably 300 Å/min or less, and further preferably 150 Å/min or less from the viewpoint of improving the polishing selectivity and shortening the polishing time.

In the polishing step using the polishing composition of the present disclosure, the polishing rate ratio (the polishing rate for the film to be polished/the polishing rate for the polishing stopper film) is preferably 5.0 or more, more preferably 10.0 or more, further preferably 20.0 or more, and still further preferably 40.0 or more from the viewpoint of shortening the polishing time. The term “polishing selectivity” in the present disclosure is synonymous with the ratio of the polishing rate for the film to be polished with respect to the polishing rate for the polishing stopper film (the polishing rate for the film to be polished/the polishing rate for the polishing stopper film). High polishing selectivity means a high polishing rate ratio.

[Polishing Method]

The present disclosure relates to a method for polishing a substrate, including a polishing step using the polishing composition of the present disclosure (hereinafter, also referred to as “polishing method of the present disclosure”).

The polishing method of the present disclosure can improve the polishing selectivity and reduce the polishing unevenness while increasing the polishing rate in the polishing step, thereby providing an effect of improving the productivity of a semiconductor substrate with improved substrate quality. The specific polishing method and polishing conditions can be the same as those described in the production method of a semiconductor substrate of the present disclosure.

The present disclosure further relates to the following compositions and production methods.

<1> A polishing composition, containing:
cerium oxide particles A;
a polysaccharide B having a weight average molecular weight of 800 or more and 2800 or less; and
water.

<2> The polishing composition according to <1>, wherein the average primary particle diameter of the particles A is preferably 5 nm or more, more preferably 10 nm or more, and further preferably 20 nm or more.

<3> The polishing composition according to <1> or <2>, wherein the average primary particle diameter of the particles A is preferably 300 nm or less, more preferably 200 nm or less, and further preferably 150 nm or less.

<4> The polishing composition according to any of <1> to <3>, wherein the content of the particles A is preferably 0.05 mass % or more, more preferably 0.10 mass % or more, and further preferably 0.20 mass % or more when the total content of the particles A, the polysaccharide B and water is assumed to be 100 mass %.

<5> The polishing composition according to any of <1> to <4>, wherein the content of the particles A is preferably 10.0 mass % or less, more preferably 7.5 mass % or less, further preferably 5.0 mass % or less, still further preferably 2.5 mass % or less, and even further preferably 1.0 mass % or less when the total content of the particles A, the polysaccharide B and water is assumed to be 100 mass %.

<6> The polishing composition according to any of <1> to <5>, wherein the weight average molecular weight of the polysaccharide B is 800 or more, preferably 850 or more, more preferably 900 or more, further preferably 1000 or more, and still further preferably 1200 or more.

<7> The polishing composition according to any of <1> to <6>, wherein the weight average molecular weight of the polysaccharide B is 2800 or less, preferably 2700 or less, more preferably 2600 or less, further preferably 2550 or less, still further preferably 2500 or less, and even further preferably 2300 or less.

<8> The polishing composition according to any of <1> to <7>, wherein the polysaccharide B is a water-soluble dietary fiber.

<9> The polishing composition according to any of <1> to <8>, wherein the polysaccharide B is at least one selected from indigestible glucan and polydextrose.

<10> The polishing composition according to any of <1> to <9>, wherein the polysaccharide B is a saccharide in which the constituent units are glucoses, or a condensate having a branched chain in which glucoses are linked by glucosidic linkage.

<11> The polishing composition according to any of <1> to <10>, wherein the number of the monosaccharides serving as the constituent units of the polysaccharide B is preferably 3 or more, more preferably 5 or more, and further preferably 10 or more.

<12> The polishing composition according to any of <1> to <11>, wherein the number of the monosaccharides serving as the constituent units of the polysaccharide B is preferably 20 or less.

<13> The polishing composition according to any of <1> to <12>, wherein the polysaccharide B is preferably a saccharide made up of 3 to 20 glucoses linked together, and more preferably a saccharide made up of 3 to 20 glucoses linked together where the constituent units are glucose only.

<14> The polishing composition according to any of <1> to <13>, wherein the content of the polysaccharide B is preferably 0.1 mass % or more, more preferably 0.2 mass % or more, further preferably 0.3 mass % or more, still further preferably 0.4 mass % or more, and even further preferably 0.5 mass % or more when the total content of the particles A, the polysaccharide B and water is assumed to be 100 mass %.

<15> The polishing composition according to any of <1> to <14>, wherein the content of the polysaccharide B is preferably 2.5 mass % or less, more preferably 2.0 mass % or less, further preferably 1.8 mass % or less, still further preferably 1.5 mass % or less, and even further preferably 1.1 mass % or less when the total content of the particles A, the polysaccharide B and water is assumed to be 100 mass %.

<16> The polishing composition according to any of <1> to <15>, wherein the content of the polysaccharide B is preferably 0.1 mass % or more and 2.0 mass % or less, more preferably 0.2 mass % or more and 1.8 mass % or less, and further preferably 0.3 mass % or more and 1.5 mass % or less.

<17> The polishing composition according to any of <1> to <16>, wherein a ratio B/A of the content of the polysaccharide B to the content of the particles A is preferably 0.01 or more, more preferably 0.1 or more, and further preferably 0.3 or more.

<18> The polishing composition according to any of <1> to <17>, wherein the ratio B/A of the content of the polysaccharide B to the content of the particles A is preferably 20 or less, more preferably 10 or less, and further preferably 5 or less.

<19> The polishing composition according to any of <1> to <18>, wherein the ratio B/A of the content of the polysaccharide B to the content of the particles A is 0.01 or more and 20 or less.

<20> The polishing composition according to any of <1> to <19>, further containing a compound C having an anionic group.

<21> The polishing composition according to <20>, wherein the weight average molecular weight of the compound C is preferably 1,000 or more, more preferably 10,000 or more, and further preferably 20,000 or more.

<22> The polishing composition according to <20> or <21>, wherein the weight average molecular weight of the compound C is preferably 5,500,000 or less, more preferably 1,000,000 or less, and further preferably 100,000 or less.

<23> The polishing composition according to <20>, wherein the compound C is a monovalent carboxylic acid.

<24> The polishing composition according to <23>, wherein the compound C is at least one selected from levulinic acid, propionic acid, vanillic acid, p-hydroxybenzoic acid, and formic acid.

<25> The polishing composition according to any of <20> to <24>, wherein the content of the compound C is preferably 0.001 mass % or more, more preferably 0.0015 mass % or more, and further preferably 0.0025 mass % or more.

<26> The polishing composition according to any of <20> to <25>, wherein the content of the compound C is preferably 1.0 mass % or less, more preferably 0.8 mass % or less, and further preferably 0.6 mass % or less.

<27> The polishing composition according to any of <20> to <26>, wherein a ratio (C/A) of the content of the compound C to the content of the particles A is preferably 0.0001 or more, more preferably 0.0005 or more, and further preferably 0.001 or more.

<28> The polishing composition according to any of <20> to <27>, wherein the ratio (C/A) of the content of the compound C to the content of the particles A is preferably 1 or less, more preferably 0.1 or less, and further preferably 0.01 or less.

<29> The polishing composition according to any of <1> to <28>, wherein a pH of the polishing composition is preferably 4.0 or more, more preferably 5.0 or more, and further preferably 6.0 or more.

<30> The polishing composition according to any of <1> to <29>, wherein the pH of the polishing composition is preferably 9.0 or less, more preferably 8.5 or less, and further preferably 8.0 or less.

<31> The polishing composition according to any of <1> to <30>, wherein the pH of the polishing composition is 4.0 or more and 9.0 or less.

<32> The polishing composition according to any of <1> to <31>, for use in polishing a silicon oxide film.

<33> The polishing composition according to any of <1> to <32>, wherein the polishing composition is composed of a first liquid in which the particles A are mixed in water and a second liquid in which the polysaccharide B is mixed in water, and the first liquid and the second liquid are mixed in use.

<34> A method for producing a semiconductor substrate, including polishing a substrate to be polished using the polishing composition according to any of <1> to <33>.

<35> A method for polishing a substrate, including polishing a substrate to be polished using the polishing composition according to any of <1> to <33>,
wherein the substrate to be polished is a substrate for producing a semiconductor substrate.

<36> A use of the polishing composition according to any of <1> to <33> for production of a semiconductor substrate.

### EXAMPLES

### 1. Preparation of Polishing Compositions (Examples 1-23 and Comparative Examples 1-11)

Water, abrasive grains (particles A), and additives (polysaccharide B and compound C) were mixed in the proportion of Tables 1-1, 1-2 and 2 below to obtain polishing compositions of Examples 1-23 and Comparative Examples 1-11. The pH of the polishing compositions was adjusted using a 0.1 N ammonium aqueous solution.

The particles A used were colloidal ceria (“ZENUS HC90” manufactured by Solvay Special Chem Japan, Ltd. (previously Anan Kasei Co., Ltd.), average primary particle diameter: 99 nm, BET specific surface area: 8.4 m²/g), amorphous ceria (baked pulverized ceria GPL-C1010, manufactured by SHOWA DENKO K.K., average primary particle diameter: 70 nm, BET specific surface area: 11.8 m²/g), ceria-coated silica (average primary particle diameter: 92.5 nm, BET specific surface area: 35.5 m²/g) and cerium hydroxide (average primary particle diameter: 5 nm, BET specific surface area: 165 m²/g).

The compounds C used were ammonium polyacrylate (weight average molecular weight: 21,000), citric acid, levulinic acid, propionic acid, vanillic acid, p-hydroxybenzoic acid, and formic acid.

The polysaccharides B used were as follows.

B1: indigestible glucan [trade name: “Fit Fiber (registered trademark) #80” manufactured by NIHON SHOKUHIN KAKO CO., LTD., water-soluble dietary fiber, branched structure]

B2: polydextrose [trade name: “Litesse (registered trademark) III” manufactured by DuPont, water-soluble dietary fiber, branched structure, a condensate of glucose/sorbitol/citric acid (89/9/11)]

B3: polydextrose [trade name: “STA-LITE (registered trademark) III” manufactured by Tate & Lyle, branched structure, a condensate produced by thermal polymerization of D-glucose in the presence of sorbitol and phosphoric acid]

B4: α-cyclodextrin [cyclic oligosaccharide, structure: six glucoses]

B5: pullulan [tradename: “PULLULAN” manufactured by FUJIFILM Wako Pure Chemical Corporation, straight-chain structure]

B6: dextrin [tradename: “Sun Deck #300” manufactured by Sanwa Starch Co., Ltd., branched structure]

The pH of the polishing compositions, the average primary particle diameter and BET specific surface area of the particles A were measured by methods below. Tables 1-1 and 1-2 show the measurement results.

(a) pH Measurement of Polishing Composition

The pH value of each polishing composition at 25° C. was measured using a pH meter (“HM-30G” manufactured by DKK-TOA CORPORATION) and was read on the pH meter one minute after dipping an electrode of the pH meter into the polishing composition.

(b) Average Primary Particle Diameter of Particles A

The average primary particle diameter (nm) of the particles A was calculated using a specific surface area S (m²/g) obtained by the following BET (nitrogen adsorption) method, with the true density of the ceria particles set as 7.2 g/cm³.

(c) Method for Measuring BET Specific Surface Area of Particles A

A dispersion liquid of the ceria particles A was dried with hot air at 120° C. for three hours and the resultant was pulverized in an agate mortar to obtain a sample. The sample obtained was dried immediately before measurement in an atmosphere at 120° C. for 15 minutes. Then, the specific surface area S (m²/g) was measured by the nitrogen adsorption (BET) method using a specific surface area measuring device (micromeritics automatic specific surface area measuring device, “FlowSorb III 2305” manufactured by Shimadzu Corporation).

### 2. Evaluation of Polishing Compositions (Examples 1-23 and Comparative Examples 1-11)

[Production of Specimen]

A silicon oxide film having a thickness of 2000 nm was formed on one side of a silicon wafer by a TEOS-plasma CVD method, and a 40 mm×40 mm square piece was cut out from the silicon oxide film to prepare a specimen of the silicon oxide film.

Similarly, a silicon nitride film having a thickness of 300 nm was formed on one side of a silicon wafer by a CVD method, and a 40 mm×40 mm square piece was cut out from the silicon nitride film to prepare a specimen of the silicon nitride film.

[Measurement of Polishing Rate for Silicon Oxide Film (Film to be Polished)]

“MA-300” manufactured by Musashino Denshi Co., Ltd. (platen diameter: 300 mm) was used as a polishing device. A rigid urethane pad “IC-1000/Sub400” manufactured by Nitta Haas Incorporated was used as a polishing pad. The polishing pad was attached onto the platen of the polishing device. The specimen was set in a holder, and the holder was placed on the polishing pad so that the surface of the specimen on which the silicon oxide film was formed would face downward (so that the silicon oxide film would face the polishing pad). Further, a weight was placed on the holder so that a load applied to the specimen would be 300 g weight/cm². The specimen of the silicon oxide film was polished by rotating both of the platen and the holder in the same rotation direction at 90 r/min for one minute while dropping the polishing composition onto the center of the platen, on which the polishing pad was attached, at a rate of 50 mL/min. After polishing, the specimen was washed with ultrapure water and dried, followed by measurement using an optical interference-type film thickness measurement device described below.

The thicknesses of the silicon oxide film before and after polishing were measured using an optical interference-type film thickness measurement device (“Lambda Ace VM-1000” manufactured by SCREEN Semiconductor Solutions Co., Ltd.). The polishing rate for the silicon oxide film was calculated from the formula below. Tables 1-1, 1-2 and 2 show the results.

Polishing rate for silicon oxide film (Å/min)=[Thickness of silicon oxide film before polishing (Å)−Thickness of silicon oxide film after polishing (Å)]/Polishing time (min)

[Measurement of Polishing Rate for Silicon Nitride Film (Polishing Stopper Film)]

The polishing and thickness measurement of the silicon nitride film were performed in the same manner as in [Measurement of polishing rate for silicon oxide film] except for the use of the silicon nitride film instead of the silicon oxide film as a specimen. The polishing rate for the silicon nitride film was calculated from the formula below. Tables 1-1, 1-2 and 2 show the results.

Polishing rate for silicon nitride film (Å/min)=[Thickness of silicon nitride film before polishing (Å)−Thickness of silicon nitride film after polishing (Å)]/Polishing time (min)

[Polishing Rate Ratio]

The ratio of the polishing rate for the silicon oxide film with respect to the polishing rate for the silicon nitride film is defined as a polishing rate ratio, and calculated from the formula below. Tables 1-1, 1-2 and 2 show the results. The larger value of the polishing rate ratio indicates higher polishing selectivity.

Polishing rate ratio=Polishing rate for silicon oxide film (Å/min)/polishing rate for silicon nitride film (Å/min)

[Method for Evaluating Polishing Unevenness]

The following evaluation method was used to measure the number of unevenness on the specimen of the silicon nitride film after polishing. First, the specimen of the silicon nitride film was photographed using “COOLPIX S3700” manufactured by Nikon Corporation with the following settings.

ISO sensitivity: 400

Image mode: 2M (1600×1200)

White balance: Fluorescent

AF-area selection: Center

AF mode: AF-S single AF

AF-assist illuminator: Off

Electronic zoom: Off

Macro: ON

Using image analysis software “WinROOF2013” manufactured by MITANI Corporation, the number of polishing unevenness in the photograph was measured under the following conditions.

The standard unit of measurement was set to 1 pixel. The photograph taken was monochromated, and a square area of 514×514 pixels inside the wafer was designated as an analysis area (hereinafter, referred to as a “designated area”) by trimming. Then, the 256-level gray scale of the inside of the designated area (actual area: 263952 pixels) was reversed to emphasize a portion where polishing unevenness was occurred for easy recognition of the polishing unevenness, and the emphasized portion was binarized with threshold of 80 to 184 and transparency of 127 using a function of the software of “Binarization with two thresholds”. Then, the shape features of the binary region were measured, and an uneven portion having different chromaticities was counted as the number of polishing unevenness. Tables 1-1, 1-2 and 2 show the measurement results.

[Evaluation of Stability]

The pH of the polishing compositions of Examples 13-23 after one month of still standing at 60° C. was measured. Table 2 shows the measurement results. The polishing composition that retained the polishing performance after one month of still standing can be judged as having favorable storage stability.

TABLE 1-1

Polishing composition

Polysaccharide B

| | | | | | | Weight |
|---|---|---|---|---|---|---|
| | Particles A | | | | | average |
| | | Content | | | Content | molecular |
| | Type | mass % | Type | | mass % | weight |
| Ex. 1 | Colloidal ceria | 0.5 | B1 | Indigestible glucan | 1.0 | 2530 |
| Ex. 2 | Colloidal ceria | 0.5 | B2 | Polydextrose | 1.0 | 1400 |
| Ex. 3 | Colloidal ceria | 0.5 | B1 | Indigestible glucan | 1.5 | 2530 |
| Ex. 4 | Colloidal ceria | 0.5 | B1 | Indigestible glucan | 0.5 | 2530 |
| Ex. 5 | Colloidal ceria | 0.5 | B3 | Polydextrose | 1.0 | 1430 |
| Comp. Ex. 1 | Colloidal ceria | 0.5 | — | — | — | — |
| Comp. Ex. 2 | Colloidal ceria | 0.5 | B4 | α-Cyclodextrin | 1.0 | 270 |
| Comp. Ex. 3 | Colloidal ceria | 0.5 | B5 | Pullulan | 1.0 | 280000 |
| Comp. Ex. 4 | Colloidal ceria | 0.5 | B6 | Dextrin | 1.0 | 2950 |
| Comp. Ex. 5 | Cerium | 0.5 | B1 | Indigestible glucan | 1.0 | 2530 |
| | hydroxide | | | | | |
| Comp. Ex. 6 | Cerium | 0.5 | — | — | — | — |
| | hydroxide | | | | | |
| Ex. 6 | Ceria-coated | 0.5 | B1 | Indigestible glucan | 1.0 | 2530 |
| | silica | | | | | |
| Comp. Ex. 7 | Ceria-coated | 0.5 | — | — | — | — |
| | silica | | | | | |
| Ex. 12 | Amorphous ceria | 0.5 | B2 | Polydextrose | 1.0 | 1400 |
| Comp. Ex. 11 | Amorphous ceria | 0.5 | — | — | — | — |

| | | | | Evaluation results | | | |
|---|---|---|---|---|---|---|---|
| | | | | Polishing | Polishing | Polishing | |
| | Polishing composition | | | rate for | rate for | rate ratio | |
| | Compound C | | | silicon | silicon | [silicon oxide | |
| | | Content | | oxide film | nitride film | film/silicon | Polishing |
| | Type | mass % | pH | [Å/min] | [Å/min] | nitride film] | uneveness |
| Ex. 1 | — | — | 6.0 | 7708 | 331 | 23 | 0 |
| Ex. 2 | — | — | 6.0 | 6997 | 368 | 19 | 0 |
| Ex. 3 | — | — | 6.0 | 6821 | 311 | 22 | 0 |
| Ex. 4 | — | — | 6.0 | 7922 | 381 | 21 | 0 |
| Ex. 5 | — | — | 6.0 | 6821 | 325 | 21 | 0 |
| Comp. Ex. 1 | — | — | 6.0 | 7341 | 1570 | 5 | 0 |
| Comp. Ex. 2 | — | — | 6.0 | 6822 | 515 | 13 | 10 |
| Comp. Ex. 3 | — | — | 6.0 | 1100 | 210 | 5 | 0 |
| Comp. Ex. 4 | — | — | 6.0 | 5817 | 396 | 15 | 3 |
| Comp. Ex. 5 | — | — | 6.0 | 143 | 34 | 4 | 0 |
| Comp. Ex. 6 | — | — | 6.0 | 3956 | 945 | 4 | 0 |
| Ex. 6 | — | — | 6.0 | 3808 | 115 | 33 | 0 |
| Comp. Ex. 7 | — | — | 6.0 | 3480 | 614 | 6 | 0 |
| Ex. 12 | — | — | 6.0 | 5201 | 294 | 18 | 0 |
| Comp. Ex. 11 | — | — | 6.0 | 5412 | 1455 | 4 | 0 |

TABLE 1-2

| | Polishing composition | | | | | | |
|---|---|---|---|---|---|---|---|
| | | | Polysaccharide B | | | | |
| | | | | | | Weight | |
| | Particles A | | | | | average | |
| | | Content | | | Content | molecular | Compound C |
| | Type | mass % | Type | | mass % | weight | Type |
| Ex. 7 | Colloidal ceria | 0.5 | B1 | Indigestible glucan | 1.0 | 2530 | — |
| Comp. Ex. 8 | Colloidal ceria | 0.5 | — | — | — | — | — |
| Ex. 8 | Colloidal ceria | 0.5 | B1 | Indigestible glucan | 1.0 | 2530 | Ammonium polyacrylate |
| Ex. 9 | Colloidal ceria | 0.5 | B2 | Polydextrose | 1.0 | 1400 | Ammonium polyacrylate |
| Ex. 10 | Colloidal ceria | 0.5 | B1 | Indigestible glucan | 1.0 | 2530 | Citric acid |
| Comp. Ex. 9 | Colloidal ceria | 0.5 | — | — | — | — | Ammonium polyacrylate |
| Ex. 11 | Colloidal ceria | 0.5 | B1 | Indigestible glucan | 1.0 | 2530 | Ammonium polyacrylate |
| Comp. Ex. 10 | Colloidal ceria | 0.5 | — | — | — | — | Ammonium polyacrylate |

| | | | Evaluation results | | | |
|---|---|---|---|---|---|---|
| | Polishing composition | | Polishing | Polishing | Polishing | |
| | Compound | | rate for | rate for | rate ratio | |
| | C | | silicon | silicon | [silicon oxide | |
| | Content | | oxide film | nitride film | film/silicon | Polishing |
| | mass % | pH | [Å/min] | [Å/min] | nitride film] | unevenness |
| Ex. 7 | — | 8.0 | 7036 | 222 | 32 | 0 |
| Comp. Ex. 8 | — | 8.0 | 6618 | 1498 | 4 | 0 |
| Ex. 8 | 0.0015 | 8.0 | 4098 | 117 | 35 | 0 |
| Ex. 9 | 0.0015 | 8.0 | 4525 | 112 | 40 | 0 |
| Ex. 10 | 0.0015 | 8.0 | 4210 | 121 | 35 | 0 |
| Comp. Ex. 9 | 0.0015 | 8.0 | 3765 | 548 | 7 | 0 |
| Ex. 11 | 0.0015 | 4.5 | 5254 | 114 | 46 | 0 |
| Comp. Ex. 10 | 0.0015 | 4.5 | 4005 | 364 | 11 | 0 |

TABLE 2

| | Polishing composition | | | | | | | | |
|---|---|---|---|---|---|---|---|---|---|
| | | | Polysaccharide B | | | | | | |
| | | | | | | Weight | | | |
| | Particles A | | | | | average | Compound C | | |
| | | Content | | | Content | molecular | | Content | |
| | Type | mass % | Type | | mass % | weight | Type | mass % | pH |
| Ex. 13 | Colloidal ceria | 0.5 | B1 | Indigestible glucan | 1.0 | 2530 | — | — | 4.5 |
| Ex. 14 | Colloidal ceria | 0.5 | B1 | Indigestible glucan | 1.0 | 2530 | Levulinic acid | 0.001 | 4.5 |
| Ex. 15 | Colloidal ceria | 0.5 | B1 | Indigestible glucan | 1.0 | 2530 | Levulinic acid | 0.1 | 4.5 |
| Ex. 16 | Colloidal ceria | 0.5 | B1 | Indigestible glucan | 1.0 | 2530 | Levulinic acid | 0.01 | 4.5 |
| Ex. 17 | Amorphous ceria | 0.5 | B1 | Indigestible glucan | 1.0 | 2530 | Levulinic acid | 0.01 | 4.5 |
| Ex. 18 | Colloidal ceria | 0.5 | B1 | Indigestible glucan | 1.0 | 2530 | Propionic acid | 0.01 | 4.5 |
| Ex. 19 | Colloidal ceria | 0.5 | B1 | Indigestible glucan | 1.0 | 2350 | Vanillic acid | 0.01 | 4.5 |
| Ex. 20 | Colloidal ceria | 0.5 | B1 | Indigestible glucan | 1.0 | 2530 | p-Hydroxybenzoic acid | 0.01 | 4.5 |
| Ex. 21 | Colloidal ceria | 0.5 | B1 | Indigestible glucan | 1.0 | 2530 | Formic acid | 0.01 | 4.5 |
| Ex. 22 | Colloidal ceria | 0.5 | B2 | Polydextrose | 1.0 | 1400 | Levulinic acid | 0.01 | 4.5 |
| Ex. 23 | Colloidal ceria | 0.5 | B2 | Polydextrose | 1.0 | 1400 | Formic acid | 0.01 | 4.5 |

| | Evaluation results | | | | | |
|---|---|---|---|---|---|---|
| | Polishing | Polishing | Polishing | | | |
| | rate for | rate for | rate ratio | | Stability | |
| | silicon oxide | silicon | [silicon oxide | | 60° C. | |
| | film | nitride film | film/silicon | Polishing | Initial | After lapse of |
| | [Å/min] | [Å/min] | nitride film] | unevenness | stage | one month |
| Ex. 13 | 6989 | 348 | 20 | 0 | 4.5 | 3.8 |
| Ex. 14 | 7139 | 335 | 21 | 0 | 4.5 | 4.0 |
| Ex. 15 | 6738 | 222 | 30 | 0 | 4.5 | 4.4 |
| Ex. 16 | 5360 | 156 | 34 | 0 | 4.5 | 4.2 |
| Ex. 17 | 4283 | 148 | 29 | 0 | 4.5 | 4.4 |
| Ex. 18 | 6742 | 274 | 25 | 0 | 4.5 | 4.2 |
| Ex. 19 | 7211 | 235 | 31 | 0 | 4.5 | 4.2 |
| Ex. 20 | 6234 | 391 | 16 | 0 | 4.5 | 4.2 |
| Ex. 21 | 6946 | 296 | 23 | 0 | 4.5 | 4.1 |
| Ex. 22 | 7287 | 188 | 39 | 0 | 4.5 | 4.2 |
| Ex. 23 | 6942 | 171 | 41 | 0 | 4.5 | 4.1 |

As shown in Tables 1-1, 1-2 and 2, the polishing compositions of Examples 1-23 containing a predetermined polysaccharide B improved the polishing selectivity and reduced the polishing unevenness while increasing the polishing rate. The polishing compositions of Examples 8-11 containing ammonium polyacrylate or citric acid as the compound C further improved the polishing selectivity. The polishing compositions of Examples 14-23 containing levulinic acid, propionic acid, vanillic acid, p-hydroxybenzoic acid, or formic acid as the compound C had favorable storage stability.

### INDUSTRIAL APPLICABILITY

The polishing composition of the present disclosure is useful in a method for producing a high density or high integration semiconductor substrate.

1. A polishing composition, comprising:
cerium oxide particles A;
a polysaccharide B having a weight average molecular weight of 800 or more and 2800 or less; and
water.

2. The polishing composition according to claim 1, for use in polishing a silicon oxide film.

3. The polishing composition according to claim 1, wherein the polysaccharide B is a water-soluble dietary fiber.

4. The polishing composition according to claim 1, wherein a content of the polysaccharide B is 0.1 mass % or more and 2.5 mass % or less.

5. The polishing composition according to claim 1, wherein a ratio B/A of the content of the polysaccharide B to a content of the cerium oxide particles A is 0.01 or more and 20 or less.

6. The polishing composition according to claim 1, further comprising a compound C having an anionic group.

7. The polishing composition according to claim 6, wherein the compound C is a monovalent carboxylic acid.

8. The polishing composition according to claim 7, wherein the compound C is at least one selected from levulinic acid, propionic acid, vanillic acid, p-hydroxybenzoic acid, and formic acid.

9. The polishing composition according to claim 1, wherein a pH of the polishing composition is 4.0 or more and 9.0 or less.

10. The polishing composition according to claim 1, wherein the polishing composition is composed of a first liquid in which the cerium oxide particles A are mixed in water and a second liquid in which the polysaccharide B is mixed in water, and the first liquid and the second liquid are mixed in use.

11. A method for producing a semiconductor substrate,
comprising polishing a substrate to be polished using the polishing composition according to claim 1.

12. A method for polishing a substrate, comprising polishing a substrate to be polished using the polishing composition according to claim 1,
wherein the substrate to be polished is a substrate for producing a semiconductor substrate.

13. (canceled)
